(19) United States
(12) Patent Application Publication
(10) Pub. No.: US 2005/0159004 A1
(43) Pub. Date: Jul. 21, 2005

(54) System for reducing corrosion effects of metallic semiconductor structures

(76) Inventors: Honglin Guo, Plano, TX (US); Joe W. McPherson, Plano, TX (US)

Correspondence Address: TEXAS INSTRUMENTS INCORPORATED, P O BOX 655474, M/S 3999, DALLAS, TX, 75265, US

(21) Appl. No.: 10/760,801

(22) Filed: Jan. 20, 2004

(51) Int. Cl. H01L 21/44; H01L 21/302; H01L 21/461

(52) U.S. Cl. 438/692; 438/687

(57) ABSTRACT

The present invention defines a system for impeding corrosive egress from a metallic trench structure (206) during the production of a semiconductor device segment (200). The system of the present invention provides a first non-metallic structure (212) and a second non-metallic structure (214). The metallic trench structure is interposed between the first and second non-metallic structures. The device segment is cleaned, after which an upper exposed surface (220) of the metallic structure is recessed (226) from an upper exposed surface (216) of the first or second non-metallic structure by a desired amount.

### TECHNICAL FIELD OF THE INVENTION

The present invention relates generally to the field of semiconductor manufacturing processes and, more particularly, to apparatus and methods for reducing detrimental corrosion effects of certain metallic semiconductor structures.

### BACKGROUND OF THE INVENTION

The continual demand for enhanced integrated circuit performance has resulted in, among other things, a dramatic reduction of semiconductor device geometries, and continual efforts to optimize the performance of every substructure within any semiconductor device. A number of improvements and innovations in fabrication processes, material composition, and layout of the active circuit levels of a semiconductor device have resulted in very high-density circuit designs. Increasingly dense circuit design has not only improved a number of performance characteristics, it has also increased the importance of, and attention to, semiconductor material properties and behaviors.

The increased packing density of the integrated circuit generates numerous challenges to the semiconductor manufacturing process. Nearly every device must be smaller without degrading operational performance of the integrated circuitry. High packing density, low heat generation, and low power consumption, with good reliability must be maintained without any functional degradation. Increased packing density of integrated circuits is usually accompanied by smaller feature size.

As integrated circuits become denser, the widths of metal structures interconnecting transistors and other devices within an integrated circuit are reduced. As the width of metal interconnects decrease, their resistance increases. As a result, semiconductor manufacturers seek to create smaller and faster devices by using, for example, a copper interconnect instead of a traditional aluminum interconnect. Unfortunately, copper—unlike aluminum—is very difficult to remove using etch technology available in most semiconductor process flows. Therefore, damascene processes have been proposed and implemented to form copper interconnects.

Damascene methods usually involve forming a trench or an opening in a dielectric layer that lies beneath and on either side of the copper-containing structures, to serve as insulation therebetween. Once the trenches or openings are formed, a blanket layer of the copper-containing material is deposited over the entire wafer, filling the trenches or openings. Electrochemical deposition (ECD) is typically the only practical method to form a blanket layer of copper. The thickness of such a layer must be at least as thick as the deepest trench or opening. After the trenches or openings are filled with the copper-containing material, the copper-containing material over them is removed by a cleaning process—chemical-mechanical planarization (CMP), for example—so as to leave the copper-containing material in the trenches and openings, but not over the dielectric or over the uppermost portion of the trench or opening.

During cleaning, copper trench structures and adjacent dielectric structures may be removed from a semiconductor wafer at different rates. For example, CMP typically involves application of a copper-selective chemical slurry, after which a first round of polishing occurs. Then, a dielectric-selective slurry is applied, followed by more polishing. In some cases, single process may be used to remove both metal and dielectric material in a relatively even manner. Regardless of which cleaning process—CMP or otherwise—is used, the ultimate goal of these processes is usually to achieve a perfect or nearly perfect planarization of all copper trench and adjacent dielectric structures.

Once planarization has been completed, a semiconductor wafer is subjected to subsequent cleaning and processing steps in a number of different apparatus. The handling, transfer, and queuing of a wafer provides a number of potential contamination sources—airborne gases or molecular particles, for example—that can cause a variety of anomalies along the exposed metal and dielectric surfaces. One such anomaly that is particularly problematic—especially in copper-based semiconductor processes—is metallic corrosion (e.g., oxidation).

The corrosion of planarized copper structures can expand from copper surfaces over the open surfaces of adjacent isolation (e.g., dielectric) structures. Left uncorrected, this reduces the effective cross-sectional area of a collateral isolation structure—significantly degrading device performance, reliability and yield. Depending upon processing conditions, corrosion can completely cover collateral structures—causing device failure and reducing yield even further. Such degradation becomes profound for smaller semiconductor geometry having smaller interconnect width and smaller space between interconnect lines.

Some conventional semiconductor processes include processing intended to clean metallic corrosion. Typically, these processes reduce the corrosion back to metal. Unfortunately, most such processes reduce the corrosion into metal in situ—leaving the resulting metal in place where the corrosion previously was. In situations where corrosion has spread out to cover adjacent dielectric structures, metal now covers the dielectric instead—resulting in the same, if not worse, reliability and yield problems.

Some conventional processes may incorporate additional processing steps, apparatus or resources to physically strip away such corrosion, using re-planarization or re-cleaning, to isolate planarized wafers in a non-reactive environment, or to establish a maximum wafer exposure time. Unfortunately, such efforts introduce certain costs, inefficiencies and poor manufacturability to semiconductor processing. Furthermore, even where such efforts are undertaken, any subsequent exposure to an ambient environment can still cause corrosion problems—until subsequent device layers have been deposited over the metallic structures in question.

As a result, there is a need for a versatile system for reducing detrimental effects of metallic corrosion on collateral isolation structures—utilizing existing semiconductor processes and materials—in an easy, efficient and cost-effective manner.

### SUMMARY OF THE INVENTION

The present invention provides a system for controlling the detrimental effects of corrosion of metallic structures on adjacent isolation structures within semiconductor wafer in an easy, efficient and cost-effective manner. The present invention is particularly applicable to controlling detrimental corrosion that occurs post-CMP. The present invention provides an optimal recession of a metallic structure that impedes outward expansion of any corrosion formed on that structure.

The system of the present invention is readily implemented within high-volume semiconductor manufacturing processes. The system of the present invention does not require additional device processing steps but, rather, manipulates existing device processes and material properties to provide an optimal result. Metallic structures within a semiconductor wafer are nominally recessed—via existing chemical, mechanical, or combined chemical/mechanical measures—such that corrosion of the metallic structure is physically confined to a certain area, leaving the effective cross-sectional area of collateral isolation structures unaffected. The present invention thus improves device reliability and yield in an efficient and effective manner, overcoming certain limitations commonly associated with most conventional systems.

More specifically, the present invention provides a method of forming a semiconductor device segment. The method comprises providing a foundation region, upon which a non-metallic structure is disposed. A metallic structure is disposed on the foundation region, immediately adjacent to the non-metallic structure. The device segment is cleaned, after which an upper exposed surface of the metallic structure is recessed from an upper exposed surface of the non-metallic structure by a desired amount.

The present invention also provides a method of impeding corrosive egress from a metallic trench structure formed during production of a semiconductor device. The method includes providing first and second non-metallic structures, between which a metallic trench structure is interposed. The device segment is cleaned, after which an upper exposed surface of the metallic structure is recessed from an upper exposed surface of the first or second non-metallic structure by a desired amount.

The present invention further provides a semiconductor device formed by a process that comprises providing a foundation, upon which a non-metallic structure is disposed. A metallic structure is disposed on the foundation immediately adjacent to the non-metallic structure. The metallic and non-metallic structures are cleaned along an upper surface of each, after which the upper exposed surface of the metallic structure is recessed from the upper exposed surface of the non-metallic structure by a desired amount.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration depicting a cross-sectional view of a semiconductor device segment; and

FIG. 2 is an illustration depicting a cross-sectional view of one embodiment of a semiconductor device segment according to the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The invention will now be described in conjunction with providing a system for controlling the detrimental effects of corrosion of metallic structures on collateral, non-metallic structures (i.e., dielectrics) within a semiconductor wafer utilizing copper interconnections. The specific embodiments discussed herein are, however, merely illustrative of specific ways to make and use the invention and do not limit the scope of the invention.

The present invention recognizes certain performance and yield degradations—caused by expansion of metallic corrosion over non-metallic structures—that are often unnoticed or ignored by conventional systems. In response, the present invention confines metallic structure corrosion in an easy, efficient and cost-effective manner.

The system of the present invention is readily implemented within high-volume semiconductor manufacturing processes. The system of the present invention does not require additional device processing steps but, rather, manipulates existing device processes and material properties to provide an optimal result. Metallic structures within a semiconductor wafer are recessed—via existing chemical, mechanical, or combined chemical/mechanical measures—such that corrosion of the metallic structure is physically confined to a certain area. The present invention thus improves device reliability and yield.

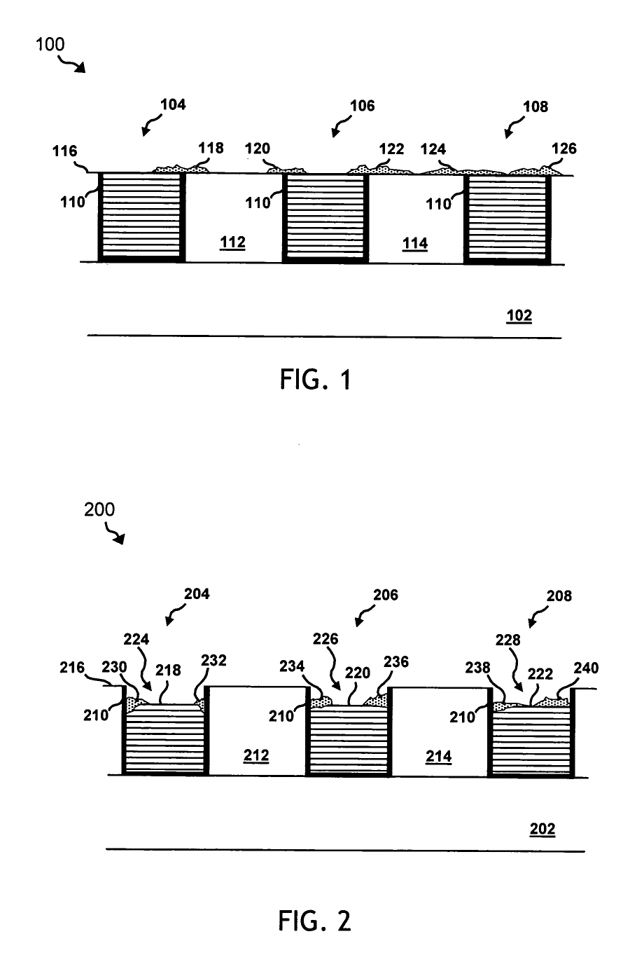

In order to fully appreciate the benefits provided by the present invention, it is useful to first examine a sample system without benefit of the present invention. Referring now to FIG. 1, an illustrative, cross-sectional, semiconductor device segment 100, without benefit of the present invention, is depicted. Segment 100 represents a semiconductor structure after planarization (e.g., CMP), but prior to deposition of higher-level materials (e.g., dielectrics, metal layers, barriers). Segment 100 comprises a pre-metal dielectric region 102, upon which three copper trench structures 104, 106 and 108 are formed. Immediately surrounding each of the copper trench structures is a barrier structure 110. Barrier 110 comprises a relatively sheer layer of a material selected to aid in deposition of the copper, to limit diffusion of the copper into adjacent structures, and to improve electrical performance of the device. Inter-metal dielectric structures 112 and 114 are disposed upon region 102, interposed between structures 104 and 106, and structures 106 and 108, respectively. Surface 116 represents the newly planarized, exposed surface of segment 100.

After surface 116 is exposed to a contaminant environment (e.g., ambient air) for some length of time, formations 118, 120, 122, 124 and 126 begin to develop along surface 116, near the outer edges of the copper trenches. Formations 118, 120, 122, 124 and 126 comprise one or more types of corrosion (e.g., oxidation), generally originating from the peripheral edges of the copper trenches. The exposed boundary area between the copper structure and adjacent structures is an area of high residue stress, which helps to promote the reaction of copper with contaminants to form corrosion. Depending upon the particular semiconductor materials used, the particular contaminants present in an environment, and the length of exposure to the environment, the relative size and spreading of formations 118, 120, 122, 124 and 126 can vary greatly—from relatively nominal sizes to relatively extensive sizes. Generally, longer exposure to a contaminant environment will generate a greater degree of corrosion. As the corrosion forms, it spreads out over the exposed surface of structures 104, 106, 108, 112, and 114—typically in a non-uniform manner. In some cases, the corrosion may only cover a small portion of the non-metallic structure, as depicted by structure 112 and formations 118 and 120. Even though the intrusion of the formations along the exposed surface of structure 112 is relatively minor, they nonetheless reduce the effective width of structure 112. In more severe cases, illustrated by structure 114 and formations 122 and 124, the formations may combine to cover the exposed surface of structure 112 completely. Even where subsequent processes reduce corrosion back into metallic copper, such copper generally stays in place—intruding upon or covering the surface of adjacent structures 112 and 114.

The resulting reduction or elimination of effective width in structures 112 or 114 causes serious device parametric and performance problems. Devices may be rendered completely inoperable, causing significant resource waste and yield loss. In other cases, certain device parametric values may be detrimentally altered in an unexpected ways—causing a number of reliability issues. For example, intrusion of copper corrosion along inter-metal dielectric can degrade device breakdown voltage significantly—indicating a poor interconnect reliability. If the anomaly is left uncorrected, the device may malfunction or fail while in use in an end equipment system.

In contrast, referring now to FIG. 2, an illustrative, cross-sectional, semiconductor device segment 200 according to the present invention is depicted. Segment 200 represents a semiconductor structure after a CMP, or other similar cleaning or planarization, process but prior to deposition of higher-level materials (e.g., metal layers, dielectrics, barriers). Segment 200 comprises a foundation region 202. In the embodiment depicted in FIG. 2, region 202 comprises a pre-metal dielectric. Three metallic trench structures 204, 206 and 208 are formed atop region 202. In the embodiment depicted in FIG. 2, trench structures 204, 206 and 208 comprise copper trench structures. Immediately surrounding each of the copper trench structures is a barrier structure 210. Barrier 210 comprises a relatively sheer layer of a material selected to aid in deposition of the copper, to limit diffusion of the copper into adjacent structures, or to improve electrical performance of the device. Non-metallic structures 212 and 214 are disposed upon region 202, interposed between structures 204 and 206, and structures 206 and 208, respectively. In the embodiment depicted in FIG. 2, structures 212 and 214 comprise inter-metal dielectric structures. Surface 216 represents the cleaned, exposed effective surface of segment 200.

According to the present invention, the post-cleaning surface 216 is not fully planarized. The exposed upper surfaces of structures 204-208 are nominally recessed just below surface 216 after CMP, or some other suitable cleaning process. The exposed surfaces of structures 212 and 214 thus define the effective surface 216 and, in most cases, should still be in planarity with one another. Similarly, although slightly recessed, the exposed surfaces 218-222 of structures 204-208, respectively, should, in most cases, also be in planarity with one another. It is possible, however, that polishing or other planarizing processes may not be able to fully, or even partially, planarize structures 204-208, 212 and 214. In such cases, these structures may have certain surface anomalies (e.g., dishing, asymmetries). The present invention comprehends and accounts for such possibilities through adjustment of recess depth, as is described hereinafter.

The recesses 224-228 atop structures 204-208, respectively, may be formed, during or prior to the cleaning process, by a number of mechanical, chemical, or combined chemical/mechanical agents already existing within a particular device manufacturing process. In one embodiment, for example, the deposition of copper within the trenches may be modified to slightly underfill each trench by a desired amount. In another embodiment, a single CMP process may utilize a chemical agent or compound that is highly copper selective—such that polishing removes more copper than dielectric—overpolishing the copper surfaces to a desired recess from dielectric surfaces. In another embodiment, a single post-CMP cleaning process may utilize a highly copper selective agent or compound to effect a desired recess by further copper reduction. In still another embodiment, the previous embodiments may be combined to both underfill and reduce the copper structures. Other methods and procedures that utilize existing production resources and provide a desired recess may be utilized in accordance with the present invention.

Exposure to a contaminant environment (e.g., ambient air) for some length of time fosters the development of formations 230, 232, 234, 236, 238 and 240. These formations begin to develop along the upper surface of each copper structure, near its outer edges. Formations 230, 232, 234, 236, 238 and 240 generally originate from the exposed copper boundary areas, due to the high residue stresses present.

Depending upon the particular semiconductor materials used, the particular contaminants present in an environment, and the length of exposure to the environment, the relative size and spreading of formations 230, 232, 234, 236, 238 and 240 may vary greatly—from relatively nominal sizes to relatively extensive sizes. Generally, longer exposure to a contaminant environment generates a greater degree of corrosion. As corrosion forms, it spreads out over surfaces 218, 220 and 222. According to the present invention, however, the recess of each copper surface to a level below its adjacent surfaces provides a boundary that confines the corrosion to the trench area. The recess of the present invention impedes any egress or spreading of corrosion onto the exposed surfaces of structures 212 and 214. Thus, by the present invention, corrosion is prevented from intruding upon structures adjacent to the metal trench structures. Effective widths of dielectrics are not reduced. Where subsequent processes reduce corrosion back into metallic copper, such copper stays within the trench.

The recesses formed according to the present invention are filled during subsequent metal depositions. Because the recesses are of a relatively nominal measure, the subsequent filling thereof incurs very little, if any, operational or performance overhead costs. According to the present invention, the relative size of a recess formed may be varied greatly, according to the specific materials used, the processes available, and the production environment conditions. Nonetheless, some practical limits do apply.

At a minimum, the recess should be at least several Angstroms deep. If the recess is too shallow, or nearly non-existent, then corrosion expansion onto non-metallic structures may not be properly impeded. Maximum recess depth may vary greatly, again depending upon the characteristics of materials and production processes used for a given device. Typically, a maximum recess depth may be on the order of several hundred Angstroms. Recess depth may have to be measured or considered as a cross-device or cross-wafer average, due to minor variances and tolerances present in most fabrication processes. In one embodiment, for example, an average recess depth of 100 Å may be selected to provide optimal results. In another embodiment, average recess depth may be varied within a range of 50 Å-150 Å, responsive to analysis of corrosion rates and effects. In still other embodiments, recess depth may be adjusted to account for localized or generalized post-cleaning surface anomalies. In such cases, average recess depth may be selected for some relatively high value (e.g., 400 Å) to account for worst-case anomaly coverage. For example, the post-CMP surfaces of two opposing dielectric structures bordering a copper trench may not be fully coplanar. In such a case, the recess depth may be adjusted to provide a minimum recession amount from the lowest dielectric surface. Any number of possible recess values or ranges may thus be utilized in accordance with the present invention.

Thus, according to the present invention, metallic structures are recessed by an amount sufficient to impede spreading of corrosion of those structures onto collateral structures. The present invention provides methods and structures that utilize existing process materials and tools to optimize device performance, yield and reliability, while incurring minimal (if any) process overhead. Furthermore, the system of the present invention may be utilized repeatedly in subsequent interconnect formation, or may be utilized independently in forming any single interconnect layer.

The embodiments and examples set forth herein are presented to best explain the present invention and its practical application and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. For example, the principles and teachings of the present invention may be applied to corrosion issues occurring with other semiconductor metals. The principles and teachings of the present invention may further be applied to any semiconductor structures where the recession of the present invention inhibits corrosive damage to collateral device structures. Many other modifications and variations are possible in light of the above teaching without departing from the spirit and scope of the following claims.

1. A method of forming a semiconductor device segment, comprising the steps of:
providing a foundation region;
providing a first non-metallic structure, disposed on the foundation region;
providing a metallic structure, disposed on the foundation region immediately adjacent to the first non-metallic structure;
cleaning the device segment;
wherein, after the cleaning, an upper exposed surface of the metallic structure is recessed from an upper exposed surface of the first non-metallic structure by less than 400 Angstroms to reduce the effects of corrosion formed on the metallic structure.

2. The method of claim 1, wherein the step of providing a foundation region further comprises providing a pre-metal dielectric foundation.

3. The method of claim 1, wherein the step of providing a first non-metallic structure further comprises providing an inter-metal dielectric structure.

4. The method of claim 1, wherein the step of providing a metallic structure further comprises providing a copper structure.

5. The method of claim 1, wherein the step of providing a metallic structure further comprises providing a metallic trench structure, interposed between the first non-metallic structure and a second non-metallic structure.

6. The method of claim 5, wherein the upper exposed surface of the metallic structure is recessed due to underfilling the trench.

7. The method of claim 1, wherein the upper exposed surface of the metallic structure is recessed due to the cleaning.

8. The method of claim 1, wherein the step of cleaning comprises cleaning utilizing a CMP process.

9. The method of claim 8, wherein the CMP process utilizes a metal selective agent.

10. The method of claim 8, wherein the CMP process overpolishes the metallic structure.

11. The method of claim 1, further comprising the step of reducing any corrosion, that forms on the upper surface of the metallic structure after cleaning, back to metal prior to further deposition of material atop the metallic structure.

12. A method of impeding corrosive egress from a metallic trench structure formed during production of a semiconductor device, the method comprising the steps of:
providing first and second non-metallic structures;
providing a metallic trench structure, interposed between the first and second non-metallic structures;
cleaning the device segment;
wherein, after cleaning, an upper exposed surface of the metallic structure is recessed from an upper exposed surface of the first or second non-metallic structure by less than 400 Angstroms to reduce the effects of corrosion formed on the metallic structure.

13. The method of claim 12, wherein the step of providing first and second non-metallic structures further comprises providing inter-metal dielectric structures.

14. The method of claim 12, wherein the step of providing a metallic trench structure further comprises providing a copper trench structure.

15. The method of claim 12, wherein the upper exposed surface of the metallic structure is recessed due to underfilling the trench.

16. The method of claim 12, wherein the upper exposed surface of the metallic structure is recessed due to the cleaning.

17. The method of claim 12, wherein the step of cleaning comprises cleaning utilizing a CMP process.

18. The method of claim 17, wherein the CMP process utilizes a metal selective agent.

19. The method of claim 17, wherein the CMP process overpolishes the metallic structure.

20. A semiconductor device formed by a process comprising the steps of:
providing a foundation;
providing a non-metallic structure, disposed on the foundation;
providing a metallic structure, disposed on the foundation immediately adjacent to the non-metallic structure;
cleaning the metallic and non-metallic structures along an upper surface of each;
wherein, after the cleaning, the upper exposed surface of the metallic structure is recessed from the upper exposed surface of the non-metallic structure by a desired amount.
